(19) United States
(12) Patent Application Publication
(10) Pub. No.: US 2011/0162881 A1
(43) Pub. Date: Jul. 7, 2011

(54) Well Seal for Electrical Wiring

(75) Inventor: Tate D. Schipporeit, Omaha, NE (US)

(73) Assignee: ELECTRICAL SPECIALISTS, INC., Gillette, WY (US)

(21) Appl. No.: 12/781,598

(22) Filed: May 17, 2010

Related U.S. Application Data
(60) Provisional application No. 61/178,869, filed on May 15, 2009.

(51) Int. Cl. H02G 15/00; H05K 13/00

(52) U.S. Cl. 174/70 R; 29/592.1

(57) ABSTRACT

In various embodiments, a well casing seal that comprises an inner sleeve containing cured material bonded to exposed electrical conductor; an outer sleeve established substantially around said inner sleeve; at least one sealer established between an outer surface of the inner sleeve and an inner surface of the outer sleeve, wherein the outer sleeve has a threaded outer surface configured to engage threads of the inner surface of a threaded power conductor hole of a wellhead mandrel. Related methods, relative to installation and manufacture are also disclosed.

This is a US non-provisional application claiming priority to U.S. provisional application No. 61/178,869, filed May 15, 2009, said provisional application incorporated by reference herein in its entirety.

### BACKGROUND

It is well know that certain wells (including but not limited to coalbed methane wells) develop pressures of up to 500 PSI that, if not contained, will result in the unwanted release of pressurized gas (e.g., methane gas) up along the well casing, through a seal, and thereafter into the free atmosphere. Of course, such release results in lost income, certainly in the case of coalbed methane, and/or the release of potentially polluting gases into the atmosphere. What compounds the problem of containing such pressures is the need to deliver electrical power to power consuming devices (e.g., water pump(s)) in the well. More specifically, well industries have found it challenging to seal pressurized fluids so that they do not escape at the site of power conductor entry/exit into/from the well casing. The problem may present itself not only in the case of electrical conductor, but, indeed, also as to any type of conveyor (particularly flexible conveyor; note that electrical conductor is an electrical power conveyor) that may enter a well casing that is at a greater pressure than the atmosphere outside of the casing.

The specific areas which have been found most difficult to seal, and through which pressurized gas most readily passes using conventional manners of sealing are immediately around power conductors at the well head, and along the surfaces of the sealing apparatus. Conventional designs often result in leaks, particularly at pressures, even at pressures as low as 20 PSI, and/or do not provide an easy-to-install apparatus. The instant application seeks to provide a simple, affordable, easy-to-install apparatus that sufficiently addresses the problem of pressurized gas release at one or more of these and possible other sites.

### BRIEF DESCRIPTION OF THE FIGURES

FIG. 1 shows a cross-sectional view of a mandrel setup for Scenarios 1 and 2.

FIG. 2 shows a mandrel having a threaded conductor pass-through hole, in addition to an inventive apparatus that may be threaded therein.

FIG. 3 shows a mandrel having a threaded conductor pass-through hole, in addition to an inventive apparatus threaded therein.

FIG. 4 shows two inventive apparatus threaded into a mandrel having two threaded conductor pass-through holes.

FIG. 5 shows a cross-sectional view of a mandrel setup for Scenario 3.

FIG. 6 shows a cut-away view of stranded, insulated wire that is soldered into one solid, non-stranded wire at an intermediate section.

FIG. 7 shows a cross-sectional view of a “threaded/no relative rotation” embodiment of the inventive apparatus from a side.

FIG. 8A shows a cross-sectional view of a “threaded/no relative rotation” embodiment of the inventive apparatus from a side.

FIG. 8B shows a cross-sectional view of a “threaded/no relative rotation” embodiment of the inventive apparatus from a side.

FIG. 8C shows a cross-section view of a wall of a “threaded/no relative rotation” embodiment of the inventive apparatus, showing in particular a possible surface treatment on the side of the wall against which curable fluid may be established.

FIG. 8D shows a cross-section view of a wall of a “threaded/no relative rotation” embodiment of the inventive apparatus, showing in particular a possible surface treatment on the side of the wall against which curable fluid may be established.

FIG. 9A shows a cross-sectional view of a “threaded/no relative rotation” embodiment of the inventive apparatus from a side.

FIG. 9B shows a cross-sectional view of a “threaded/no relative rotation” embodiment of the inventive apparatus from a side.

FIG. 9C shows a cross-sectional view of a “threaded/no relative rotation” embodiment of the inventive apparatus from a side.

FIG. 10 shows a photo of a “threaded/no relative rotation” embodiment of the inventive apparatus.

FIG. 11 shows a photo of a “threaded/no relative rotation” embodiment of the inventive apparatus.

FIG. 12 shows a photo of a “threaded/no relative rotation” embodiment of the inventive apparatus from several perspectives (two side views, cross-sectional, top).

FIG. 13 shows a cross-sectional view of a “threaded/relative rotation” embodiment of the inventive apparatus.

FIG. 14 shows a photo of a “threaded/no relative rotation” embodiment of the inventive apparatus.

FIG. 15 shows a cross-sectional view of a sleeved, “threaded/relative rotation” embodiment of the inventive apparatus.

FIG. 16 shows a cross-sectional view of an unsleeved, “threaded/relative rotation” embodiment of the inventive apparatus; wires shown are stripped of their insulation for a portion of their passage through the cured material.

FIG. 17 shows a specification sheet for a “threaded/relative rotation” embodiment of the inventive apparatus.

FIG. 18 shows a specification sheet for a “threaded/no relative rotation” embodiment of the inventive apparatus, showing in particular a plug-type connection.

FIG. 19 shows a photo of a “threaded/relative rotation” embodiment of the inventive apparatus.

FIG. 20 shows a cross-sectional view of a “non-threaded power conductor hole” embodiment of the inventive apparatus.

FIG. 22 shows a specification sheet for components of a “non-threaded power conductor hole” embodiment of the inventive apparatus.

FIG. 23 shows a specification sheet for components of a “non-threaded power conductor hole” embodiment of the inventive apparatus, in addition to the wires that pass therethrough.

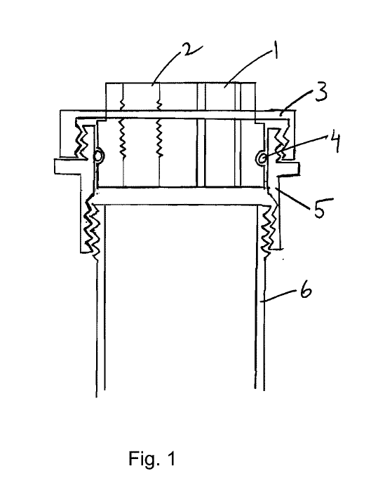

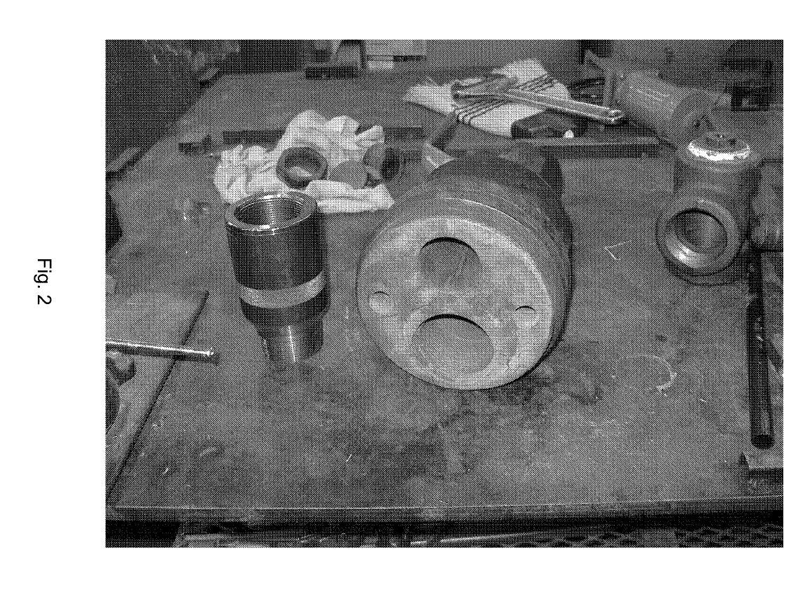

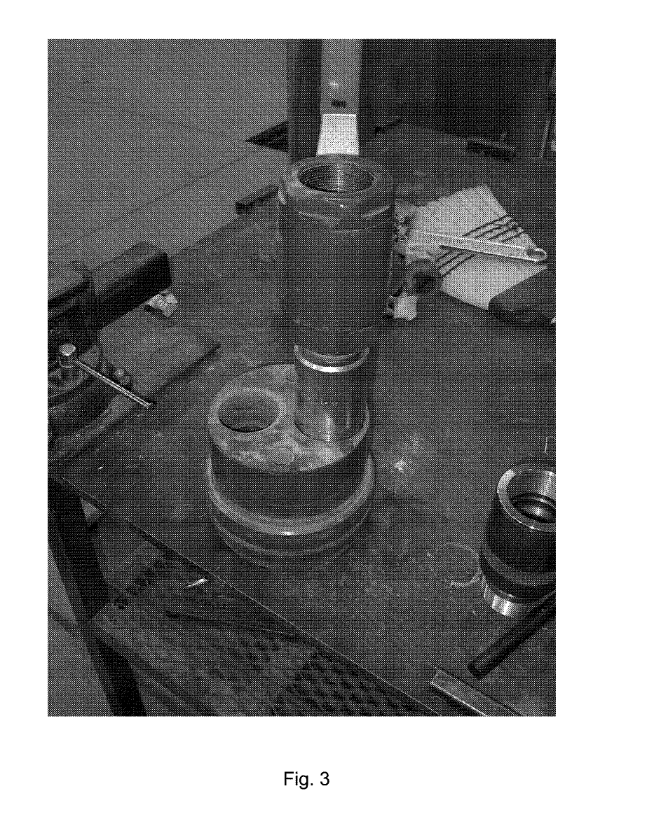

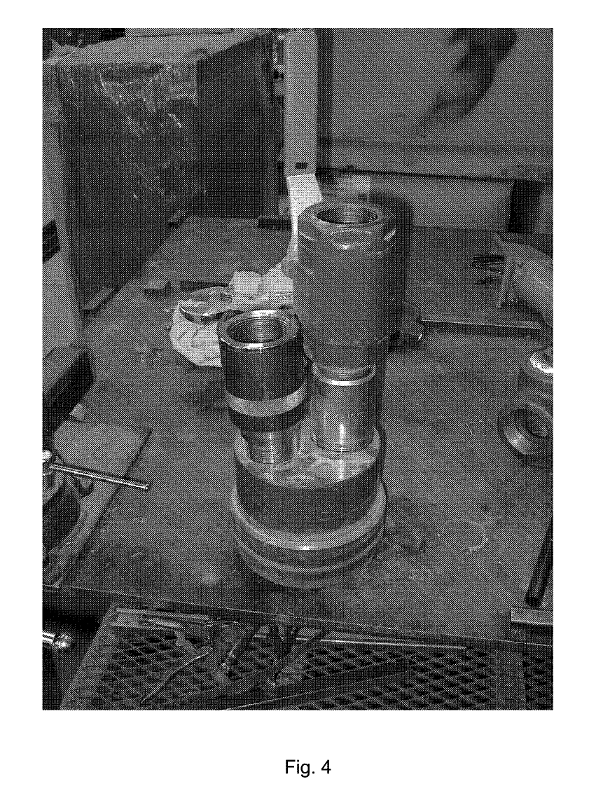

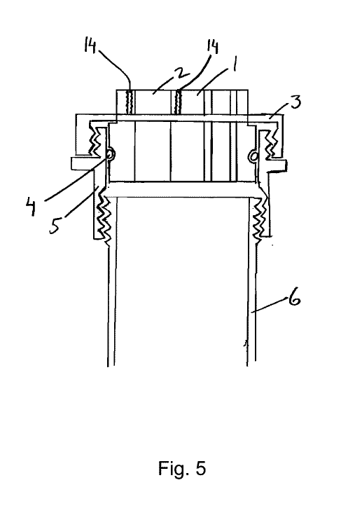

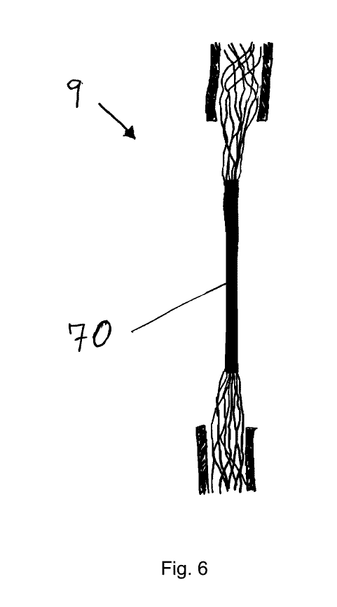

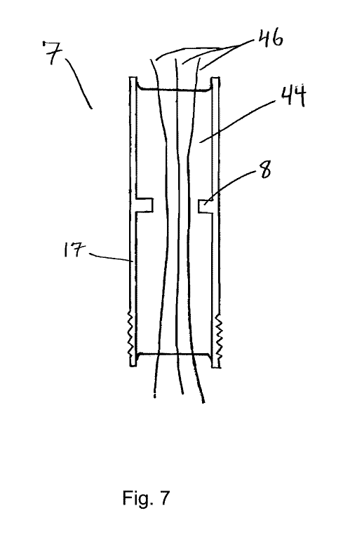

### DETAILED DESCRIPTION OF THE PREFERRED EMBODIMENTS

As mentioned earlier, the present invention includes a variety of aspects, which may be combined in different ways. The following descriptions are provided to list elements and describe some of the embodiments of the present invention. These elements are listed with initial embodiments, however it should be understood that they may be combined in any manner and in any number to create additional embodiments. The variously described examples and preferred embodiments should not be construed to limit the present invention to only the explicitly described systems, techniques, and applications. Further, this description should be understood to support and encompass descriptions and claims of all the various embodiments, systems, techniques, methods, devices, and applications with any number of the disclosed elements, with each element alone, and also with any and all various permutations and combinations of all elements in this or any subsequent application.

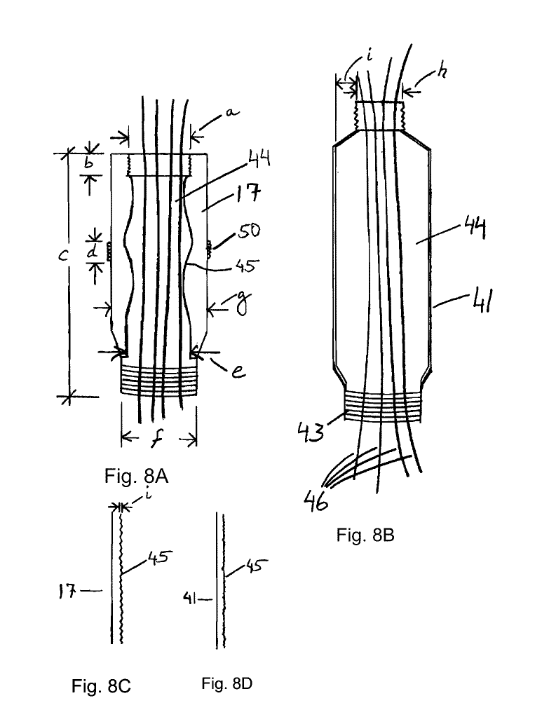

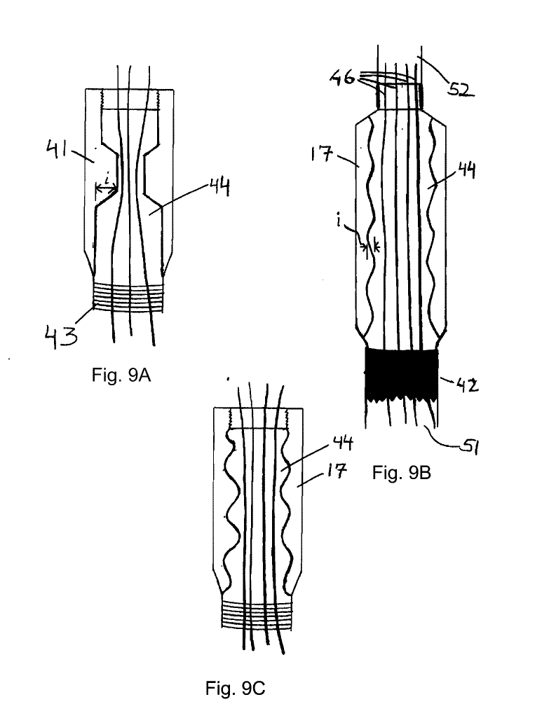

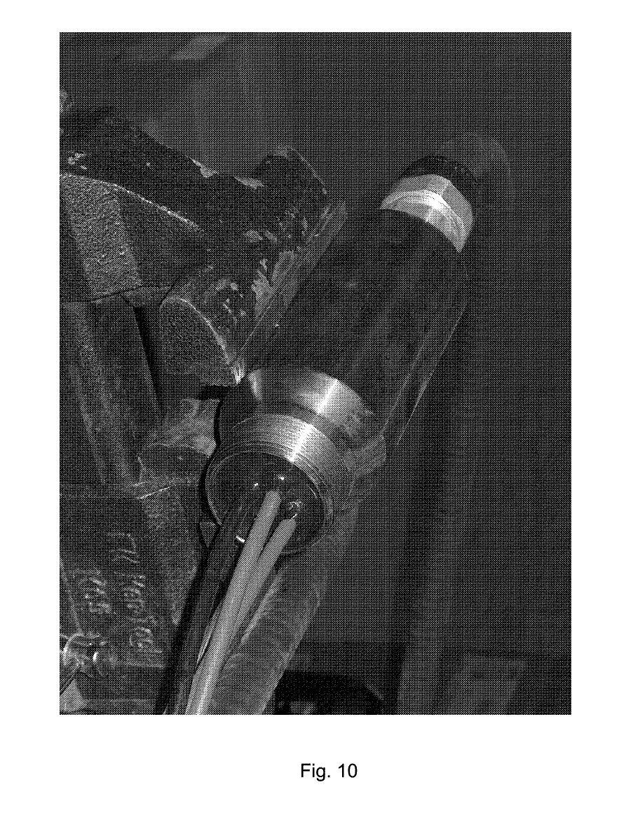

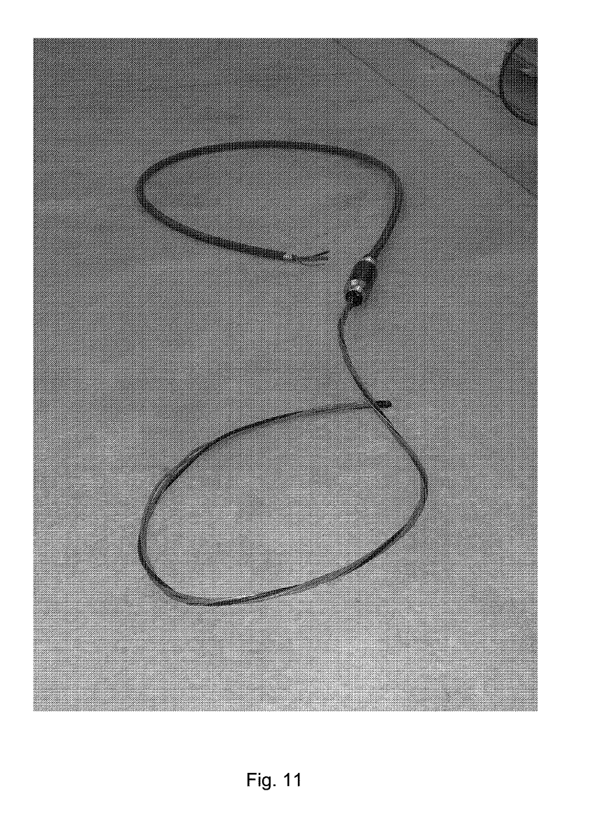

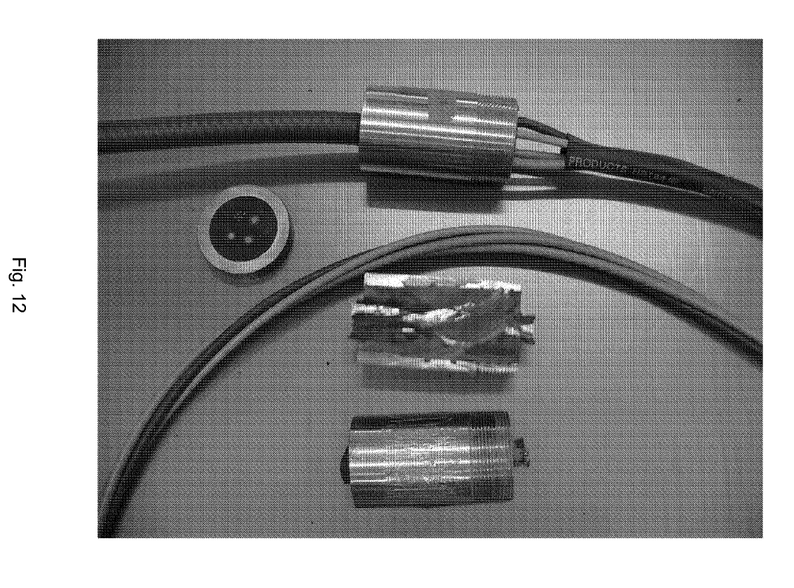

In certain embodiments, there may be provided, perhaps through geometric design (see, e.g., FIGS. 8A, 9A-C) of the inside of the apparatus sleeve that interfaces with epoxy, or through surface treatment (see, e.g., FIGS. 8C, 8D) of the inside of the apparatus housing, a manner of enhancing the prevention of any type of failure that might allow a leak of pressure. Such surface treatments may include any that increase the dislocation force of the cured material 44 relative to the inner surface of a metal, inner cylindrical sleeve against which it is established (i.e., that force needed to dislodge the cured material from its position within the apparatus housing). More specific examples of surface treatment include: surface roughening, surface knurling, surface indentation, surface protrusions, machined surface rings, all of which may effect radial surface variations at various housing axis locations (differences in the radius of the inner surface at different locations along the housing axis) of not more than 3 mm (dimension “i”).

Any radial surface variations at various housing axis locations that are larger than 2 mm are referred to as geometric variations 8 of the housing inner surface. Geometric design that may be used (instead of or in addition to surface treatment) may be any of countless types of shapes; small grooves as shown in FIGS. 8C, 8D are one such type of shape.

The figures show simply a few of the many different possible surface treatments and/or geometric variations possible. It is of note that neither surface treatment nor geometric variation of the inner surface of the apparatus housing are requisite features of the inventive technology, as indeed a curable fluid 44, upon curing to become a cured material may prevent pressure leaks simply through: (a) the adhesion (i.e., “bonding”) of the cured material to the inner surface of the inner sleeve and to the outer surface of the conductor(s) (or insulation fused thereto) passing therethrough; and (b) the impermeability, under design pressures, of the cured material itself.

It is of note that certain embodiments of the inventive technology may also include surface treatment and/or geometric variations in order to prevent any dislodging or shifting of the cured material relative to the apparatus housing in a direction towards the environment that, typically pressurized above that pressure found on an opposite side of the apparatus, may, for certain reasons, be depressurized, whether intentionally or otherwise. An exemplary geometric variation shown in the figures is a cone-type variation at the bottom of a well seal apparatus as shown in FIGS. 8B and 9B. It is of note that although the surface treatment and/or geometric variations are shown on what are referred to as “threaded/no relative rotation” apparatus, such surface treatment and/or geometric variations may be used on any of the other apparatus (i.e., the “threaded/relative rotation” apparatus and the “non-threaded power conductor hole” apparatus).

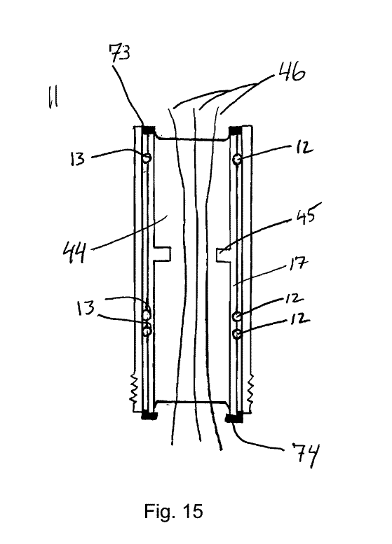

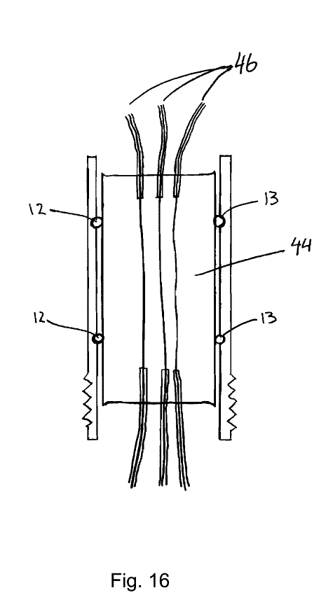

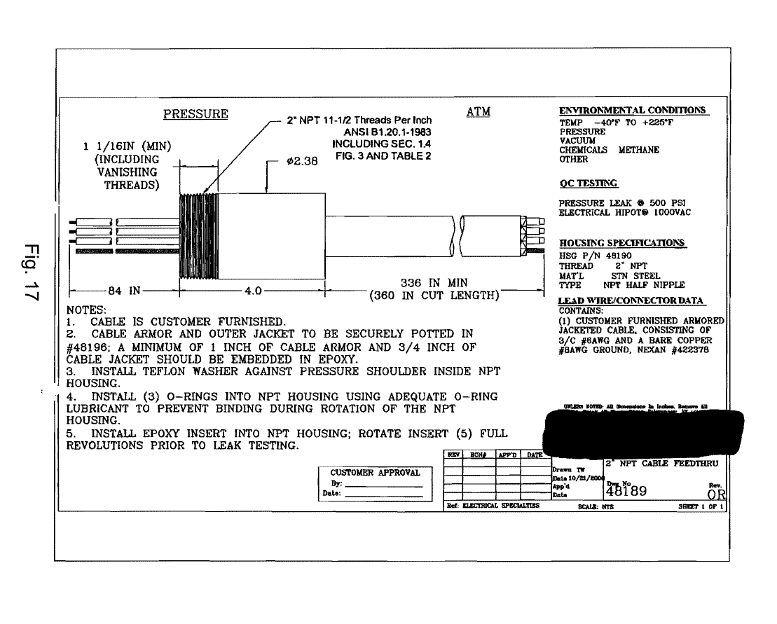

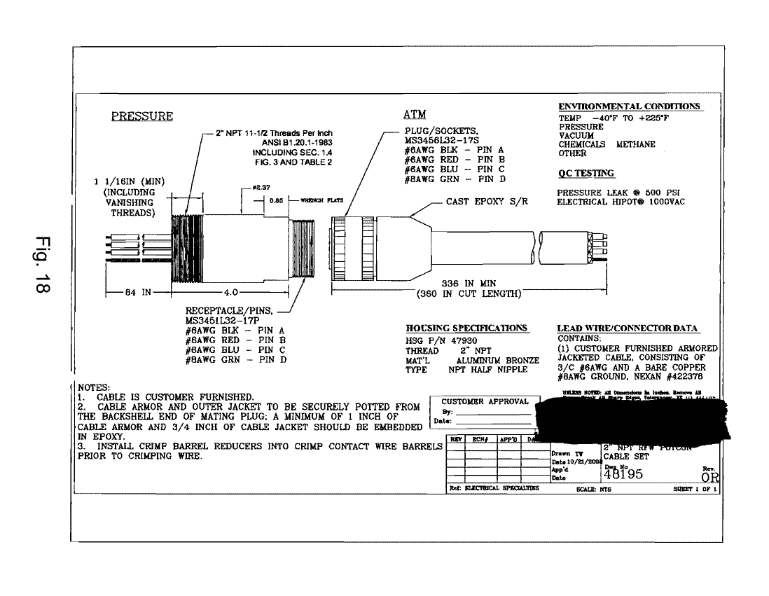

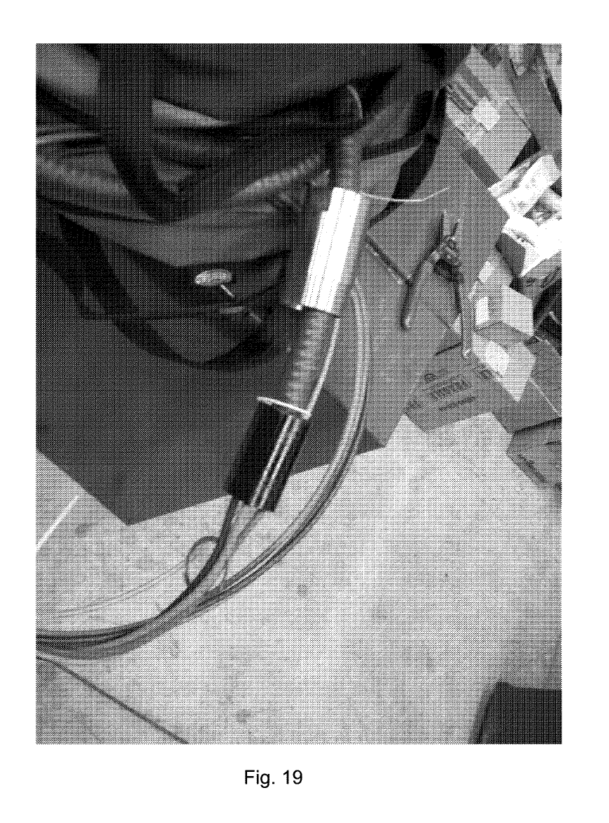

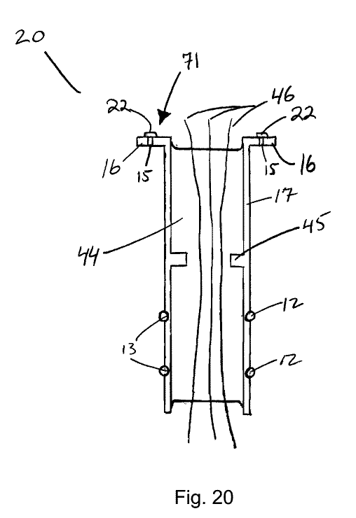

Of course, given the fact that typically a non-negligible area of the cured material is exposed to the pressurized fluid (whether gas or liquid) below (or more generally, on one side of the apparatus), a significant force may develop against such cured material face; such force tends to dislodge the cured material from its position within the cavity of the apparatus housing. As such, features on the internal walls of the cured material filled sleeve (e.g., geometric variation 45 as shown in FIG. 15) may be incorporated to decrease the risk of such dislodging. Of course, FIG. 15 (and FIGS. 8 and 9) show only one example of such featuring; there are perhaps an unlimited number of different types of features that may adequately secure the cured epoxy against design forces anticipated during operation.

As preferred embodiments of the inventive technology involve cured material which, by definition is hardened, the wires that are set therein may be permanently set therein (at least those parts of the wires between the two ends of the cured material). As such, the apparatus may, in some respects, be considered disposable, as the wiring cannot be removed from the apparatus' epoxy filled sleeve once the curable material has hardened. However, even such designs may be removed from a specific well and perhaps used in another well. Removal of the apparatus may be facilitated by a knurl 50 (e.g., a diamond knurl) on the outer surface of the apparatus housing. Of course, this is an optional feature.

There are three commonly encountered customer-driven scenarios that the inventive apparatus are designed to accommodate. As such, regardless of which of the three scenarios a customer desiring an effective and facile pressure seal presents, one of the inventive apparatus can be used to meet customer need in that customer's specific situation. The three different scenarios are as follows:

Scenario 1: A customer has a mandrel 1 that has a power conductor hole 2 that has a threaded inner surface, and rotating power cables during installation/removal of the apparatus does not pose a problem (i.e., is not undesirable). In Scenario 1, the apparatus with a threaded outer housing that is “rotationally fixed” relative to the cables that pass through it may be used (the “threaded/no relative rotation” apparatus 7).

Scenario 2: A customer has a mandrel 1 that has a power conductor hole 2 that has a threaded inner surface, and rotating power cables (during installation or removal of the apparatus) is undesirable. In Scenario 2, the apparatus with a threaded outer housing that is rotatable relative to the cables that pass through it may be used (the “threaded/relative rotation” apparatus 11).

Scenario 3: A customer has a mandrel 1 that has a power conductor hole 2 that has a smooth inner surface. In Scenario 3, the apparatus which, instead of threads, has o-rings around its outer surface, and which may be secured to the mandrel 1 via, e.g., bolts through bolt holes in a flange at the top of the apparatus (the “non-threaded power conductor hole” apparatus 20).

Each apparatus is designed to be established in the mandrel's power conductor hole 2; the mandrel itself typically creates a seal with a base 5 in which it is established through the use of o-rings 4. The base is typically threaded onto the often threaded upper opening of the well casing 42. The mandrel may be held in place with a retainer nut 3 that secures the mandrel in fixed position relative to the base. An interference fit may provide a lower “support” against which the mandrel may be advanced and secured via threaded engagement.

Although there are indeed at least three different embodiments (to accommodate the three different scenarios indicated above), each embodiment will preferably share a common feature—a metal, inner cylindrical sleeve 17 defining a central space (e.g., typically substantially cylindrical, although it can be of a different shape) that is open at each end, through which electrical conductor(s) 46 may travel (from one open end to the other) and in which curable fluid 44 (e.g., epoxy or other curable fluid) may be placed. The curable fluid, when established around the wires 46 and after curing, prevents pressure leaks along the wiring and along the interface of the inner surface of the sleeve and the cured material.

In order to assure a leak tight seal, it must be assured that either: at least a portion of a wire's travel through the epoxy is solid (whether such solid wire is created upon soldering stranded wire or, instead, purchased as solid); or individual strands of stranded wires are sufficiently separated from one another such that curable fluid may bond around each of the wires. If stranded wire is neither tinned (soldered, as indicated above), or has its strands sufficiently separated from each other), pressurized fluid leak route(s) develop along the spaces (interstices) between the inner surfaces of the strands.

The reason why solid (i.e., non-stranded wire) wire is typically not simply purchased and used for that portion of the wire that passes through the epoxy is complications arising from splicing with the preferred (and often already situated) stranded wires below the wellhead. Further, stranded wire is easier to manage. However, it is of note that spliced wire that is soldered so that it is “solid” at some point in the inner sleeve is not a requisite feature of the invention, as indeed, in some applications, solid wire (that was at no prior time stranded and thereafter soldered) may be used through the epoxy, and, indeed, individual strands may possibly be separated from one another so that curable fluid may flow substantially around all such individual strands (and upon hardening and bonding to the individual strands, preclude the passage of pressurized fluid along the surfaces of such individual strands).

It is of note that in any embodiment, it may be preferred to use stranded wire, and to solder that wire together so that for at least a portion of that wire's passage through the epoxy, such stranded wire is soldered together (effectively forming a solid wire). Again, the reason for such soldering includes prevention of pressure leaks along internal surfaces of stranded wire that are not fused with epoxy. The reason why it may be preferable to use such stranded wire in the first place (instead of replacing it with solid wire) is ease of handling of the stranded wire. Whether the wire is stranded or not, it will typically be necessary to remove the insulation from the wire at some point during the wire's passage through the epoxy filled inner sleeve.

In cases where solid wiring that was never previously stranded is used, it is of note that often, because such solid wiring typically has insulation, and typically such insulation is a sheath or jacket that is typically not fused to the metal conductor itself, it may be necessary to either strip the insulation from the insulated wire, leaving exposed, uninsulated solid wire, or simply purchase exposed, uninsulated wire, and use that exposed, uninsulated solid wire to pass through at least a portion of the epoxy-filled cavity. Such epoxy-on-bare wire “bonding” (or fusion) will act as an obstacle to pressurized fluid leaks along the conductor. Leaks along the inner surface of the sleeve 17 are prevented by the bonding of the epoxy 44 with the inner surfaces of the inner sleeve, while other leaks are prevented simply by the bulk, cured epoxy (and its bonding with the exposed electrical conductor). If the insulation of an unstranded conductor, as that conductor is purchased, is bonded to the metal conductor (such that pressurized fluid will not leak between the bare metal wire and the insulation therearound), then it may not be necessary to strip the wire at all (or may not be necessary to purchase bare, uninsulated wire); in such case, the wire's insulation is considered cured material and the insulated electrical conductor is considered exposed electrical conductor. It is of note that where it is desired to solder stranded wire to create the solid wire portion that passes through the epoxy, to perform such soldering, it is of course necessary to remove any insulation first.

It is of note that the entire length of the exposed electrical conductor(s) (e.g., bare copper wire, or uninsulated, soldered, formerly stranded wire) that passes through the epoxy need not be bonded to cured material, as indeed if only a portion thereof is so fused, such may be sufficient to prevent leaks along such wire. However, generally, the greater the portion of a conductor traveling through the cavity that is so bonded, the less the risk of pressure leaks along such conductor (which includes bare metal, uninsulated conductors and conductors with insulation fused to the bare metal wire).

Again, the epoxy-filled sleeve (or more generally, cured material filled sleeve) above is, typically, common to all three designs (again each design intended to accommodate a different scenario that customers may present). What distinguishes each of the three designs are other features. More particulars follow:

In Scenario 1 (the threaded/no relative rotation apparatus), there are threads on the outer surface of the epoxy filled sleeve enabling engagement of such sleeve with the threaded, inner surface of the power conductor hole through the mandrel 1; as such, the epoxy-filled sleeve is the outer housing of the apparatus, and it is threaded. Again, twisting of the wires passing through the apparatus (that is threaded into the power conductor hole) is acceptable.

In Scenario 2 (the threaded/relative rotation apparatus), there are no threads on the outer surface of the inner epoxy contiguity that is rotatable relative to the outer sleeve (whether such contiguity be an epoxy-filled sleeve or an epoxy slug without a sleeve around it) to engage the inner surface of the power conductor hole through the mandrel 1, but there is an outer sleeve established around the inner epoxy contiguity (e.g., cured material in cylindrical form without a surrounding metal sleeve to which it is bonded, or metal, inner cylindrical sleeve that contains cured material) and there are threads on the outer surface of that outer sleeve to engage the inner surface of the power conductor hole through the mandrel 1. In this threaded/relative rotation apparatus, there are sealers 12 such as, preferably, at least one o-ring established between the inner epoxy contiguity (again, whether it has a sleeve or not) and the outer sleeve. Such sealer(s), particularly when lubricated, allow rotation of the outer sleeve about the metal, inner cylindrical sleeve (or, more generally, the inner epoxy contiguity); each sealer may be established in a retention groove(s) 13 in the inner surface of the outer sleeve and/or a retention groove in the outer surface of the inner epoxy contiguity, or there may be two retention grooves for each of the one or more sealers (one groove as part of the outer surface of the inner sleeve and one groove oppositely established as part of the inner surface of the outer sleeve). Where there are two retention grooves for each of the one or more sealers, such grooves (and indeed the sealer established in them) may act as an inner sleeve securer (that retains the inner sleeve in fixed vertical position relative to the mandrel), as indeed such a configuration may prevent vertical motion of the inner sleeve relative to the mandrel. As with any embodiment that includes o-rings in some fashion, lubricant may be used.

It is of note that there may be two sub-embodiments of the Scenario 2 design: (1) the outer sleeve may preferably be installed separately from (and before) installation of the inner sleeve (as such, the outer sleeve and the inner sleeve may be either separate at purchase or easily removed from each other); and (2) the outer sleeve and the inner sleeve may preferably be installed at the same time (as such the outer sleeve and the inner sleeve may be purchased as one integral unit to be installed together such that upon threading of the outer sleeve into the mandrel 1's power conductor hole, the inner sleeve is installed therewith). It is of note that during installation of the second sub-embodiment of Scenario 2, in order to prevent rotation of the inner sleeve while the outer sleeve is threaded into the mandrel 1's threaded power conductor hole, it may be necessary to somehow prevent such rotation; in some embodiments, that may be as simple as manually grasping the epoxied cables that come out of the top of the inner epoxy contiguity. In others, it may be necessary to use a tool to prevent such rotation. It is also of note that during installation of the first sub-embodiment of Scenario 2, after the outer sleeve is screwed into the threaded power conductor hole of the mandrel 1, the inner sleeve may simply be forced directly down into the outer sleeve (again, o-rings or other sealers would provide the seal between the inner and outer sleeve). The inner sleeve, once established inside the outer sleeve (again, with sealer such as one or more o-rings therebetween), may be secured into position in a variety of manners (bolts passing through holes in a flange at the top of the inner epoxy contiguity (where it is a sleeve) and into threaded bolt holes in either the mandrel 1 or the top of the outer sleeve, or use of sealer retention grooves as explained above, as but a few examples). This manner of securing may be similar to the manner in which the “non-threaded power conductor hole” apparatus of Scenario 3 is secured. An interference fit or a stop may prevent the downward movement of the inner sleeve when it is secured (e.g., when bolted down).

In Scenario 3 (the “non-threaded power conductor hole” apparatus), the apparatus, instead of having threads on the outer surface of the epoxy contiguity (which, as above, may have an outer sleeve (preferably metal) or not), has sealers 12 (e.g., o-rings) around such outer surface. Further, this apparatus embodiment includes some manner of securing the apparatus to the mandrel 1 from the top (in the case where the epoxy contiguity includes a sleeve, via, e.g., bolts through bolt pass through holes 15 in a flange 16 at the top of the apparatus, where such bolts are then threaded into threaded bolt holes 14 in the mandrel 1). An interference fit or a stop may prevent the downward movement of the epoxy contiguity when it is secured (e.g., when bolted down). As with any o-ring embodiment, lubricant may be used to facilitate relative motion of the surfaces on either side of the o-rings, and to enhance the sealing effect.

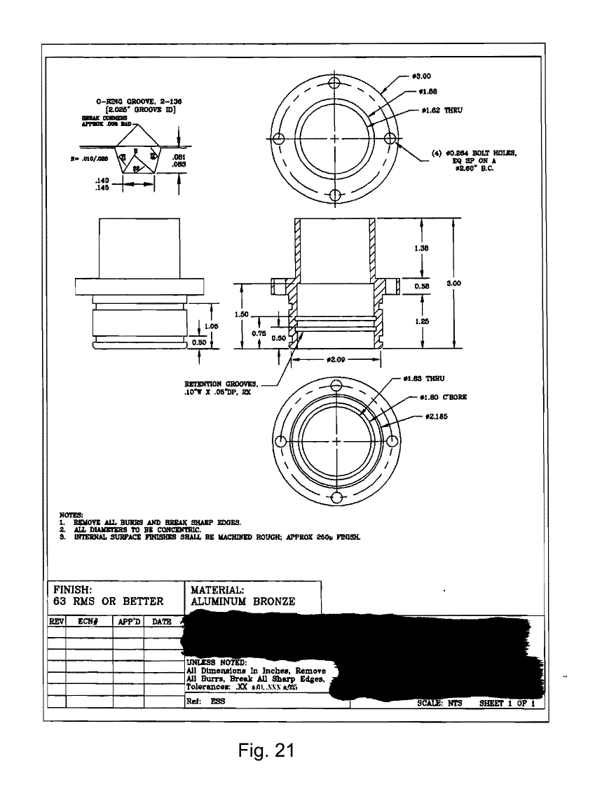

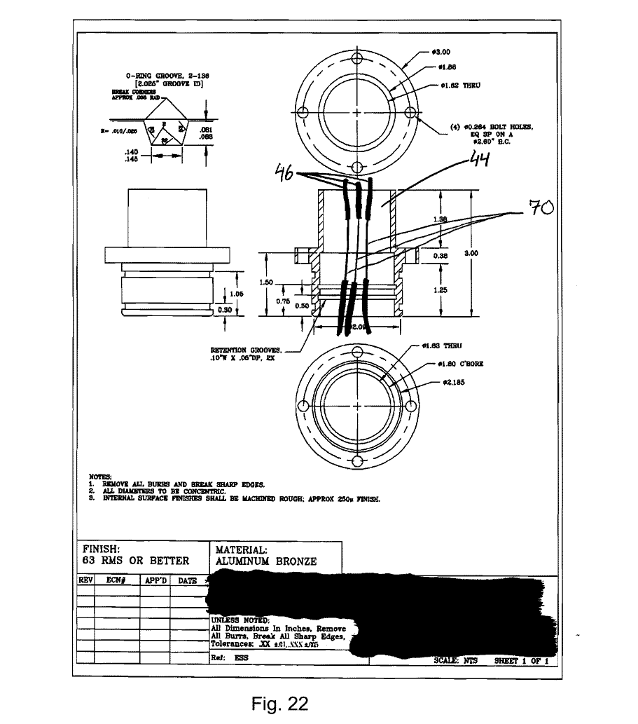

The embodiment shown in FIGS. 22-24 (“non-threaded power conductor hole” apparatus) shows an inventive apparatus housing that may have o-ring grooves on its outside surface, into which o-rings may be established, to enable sealing, without threads. Of course, an interference fit, whereby the elastic sealer(s) are compressed between the outer surface of the epoxy contiguity (sleeved or unsleeved) and the inner surface of the power conductor hole of the mandrel 1, may prevent pressurized fluid leaks between the surfaces. For a given well casing 6, a proper interference fit may be found upon proper design/selection of: o-rings, o-ring grooves, and size of the outer surface of the part of the epoxy contiguity that is established within the base. A flange with bolt holes may act to enable fastening/securement of the epoxy contiguity in fixed position relative to the casing 6. In embodiments with o-rings, (a broad term that includes not only rings with circular cross-section, but also rings with non-circular cross-section), o-ring grooves may be established on the inner surface of the outer sleeve and/or the outer surface of the inner sleeve. Of course, o-rings (whether circular in cross-section or not) are not the only type of pressure sealer that may be used—gaskets may also, or instead, be used, particularly where established under the flange of the apparatus housing, between the flange and a portion of the mandrel 1 disposed against the flange (e.g., an upper rim of the power conductor hole in the mandrel 1). Typically, where used, a gasket would be established such that tightening of bolts (e.g., bolts through a flange) compresses the gasket, thereby enhancing the pressure seal afforded by the gasket. A gasket could find similar use in certain “threaded/relative rotation apparatus.”

It is of note that the use of NPT threads in any embodiment having threads may prove advantageous, as indeed, upon engagement, they are self-sealing (material removed during threading obstructs a spiral flow leak path).

It is of note that the inventive technology is not limited to only to pressurized wells where a conductor must pass through the seal, but indeed is applicable in any situation where a pressure tight seal is needed between a first pressurized environment 51 (the inside of a well casing, as but one example) and a second environment 52, where the first pressurized environment has a greater pressure than the second environment (which may be pressurized, as in the case of the atmosphere, but need not be), and where at least one conductor 46 (e.g., a flexible conductor) must pass through the seal. As mentioned, the conductors include but are not limited to electrical wires.

Exemplary dimensions, which may apply to any of the figures that have some sort of featuring (see FIGS. 8-9), may be as follows:

a: 2″

b: ¾″

c: 5½″

d: 1″

e: 1.9″

f: 2″

g: 2.375″

h: 1″

As mentioned, these values are merely examples of the multitude of dimensions that could apply for various embodiments of the inventive technology. Further, surface features/treatment are not a necessary aspect of the inventive technology.

At least one embodiment of the inventive technology may be described as a pressure tight seal apparatus (i.e., and apparatus that can prevent the leakage of fluid under design pressures) comprising: a metal, inner cylindrical sleeve 17 defining a sleeve axis 60 (i.e., the longitudinal axis of the sleeve) and having two ends 61, 62 (in installation mode, typically a bottom end and a top end), an inner surface 63 and an outer surface 64 (both typically metal); cured material (e.g., epoxy, such as flame resistant or fireproof epoxy) that fills at least an axial portion (⅘'s, or substantially all of the length, as but two examples) of the metal, inner cylindrical sleeve 17 (e.g., so as to form a cured material core within the metal, inner cylindrical sleeve 17 that obstructs passage of pressurized fluid from one end of the inner sleeve to another).

The apparatus may further comprise a metal, outer cylindrical sleeve 65 having an outer surface 66 with threads 67 configured to engage threads of an inner surface of a power conductor hole 2 of a mandrel 1 (e.g., as where the threads have the same pitch and appropriately sized corresponding diameters (even where they are NPT threads). The metal, outer cylindrical sleeve 66 may be established substantially around the metal, inner cylindrical sleeve 17 and have an inner surface 68. The apparatus may further comprise a spatial gap 69 between the metal, inner cylindrical sleeve 17 and the metal, outer cylindrical sleeve 65; at least one elastomeric sealer 14 (e.g., at least one rubber o-ring) established around the outer surface of the metal, inner cylindrical sleeve 17 and between the outer surface 66 and the inner surface 68 of the metal, outer cylindrical sleeve 65, and in contact with both the surfaces; at least one electrical wire 46 passing from one of the two ends of the metal, inner cylindrical sleeve 17 to the other of the two ends, each of the at least one electrical wire having at least a portion within the cured material 44 that is exposed electrical conductor 70; and an inner cylindrical sleeve securer 71 that secures the metal, inner cylindrical sleeve 17 in fixed vertical position relative to the mandrel 1 (i.e., such that the metal, inner cylindrical sleeve 17 does not move vertically relative to the mandrel 1 when in installed configuration).

The term exposed electrical conductor includes not only wires (whether stranded or not) whose electrical insulation has been stripped from the electrical conductor, but also metal (e.g., copper) conductor that has never had insulation. In the case of unstranded wire, exposed merely means without insulation; in the case of stranded wire, the term exposed means uninsulated and that all individual strands are either: soldered (or tinned) together; or all individual strands are sufficiently separated (e.g., by forcing ends of the uninsulated stranded portion together) before potting, or curing of curable fluid 44, such that curable material may flow entirely around each strand (thereby blocking any interstitial fluid passages between the individual strands that may otherwise exist). The term electrical wire is that which can conduct electricity along the path defined by the wire, whether insulated or not, or stranded or not.

In preferred embodiments, the cured material is bonded to the inner surface of the metal, inner cylindrical sleeve 17 and to each the exposed electrical conductor 70. Such bonding is the to exist where leakage of pressurized fluid along interfaces of the metal (whether it be an exposed electrical conductor or an inner sleeve surface) with the epoxy is prevented. The elastomeric sealer 14 and the curable fluid 44 (e.g., epoxy) may be flame resistant, or preferably, fireproof. Available flame resistant or fireproof curable fluid (e.g., epoxies) and elastomeric sealers 14 (e.g., rubber o-rings, such as neoprene o-rings) are well known and readily available.

In certain embodiments, the exposed electrical conductor 70 of at least one of the at least one electrical wires 46 is soldered, formerly stranded wire. Soldered wire may be preferred for its ease of handling; soldering of stranded wires may eliminate the possibility of leakage of pressurized fluid between strands. Coupled with a bonding (adhesion) of the cured material to the soldered wire (and to the inner surface of the metal, inner cylindrical sleeve), the soldering results in a pressure tight inner cylindrical sleeve seal. Of course, when such sleeve is established within an outer sleeve that is threadedly engaged with the inner surface of a threaded power conductor hole 2, and elastomeric sealer 14 is established between the two sleeves, the power conductor hole 2 is pressure tight and pressures anticipated under expected well operating conditions (i.e., design pressures) will not leak through the power conductor hole 2.

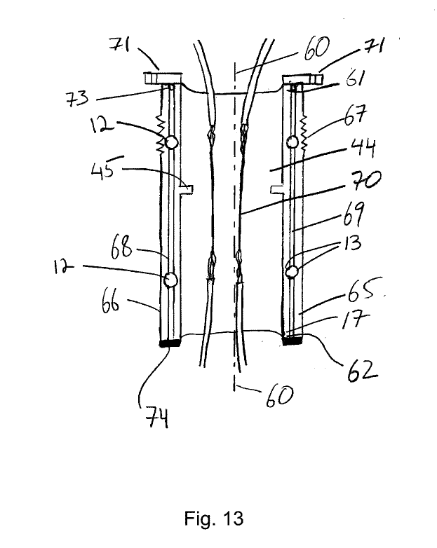

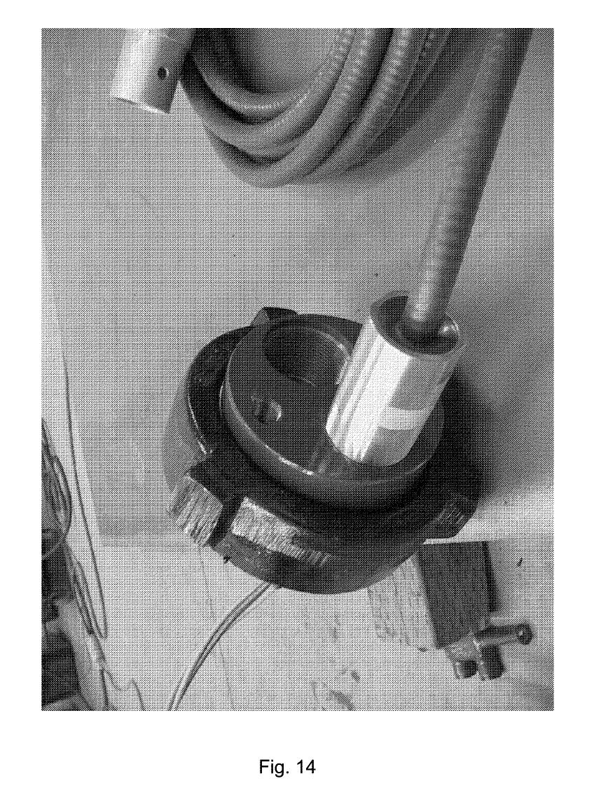

At least one elastomeric seal retention groove 13 may be established as part of the outer surface of the metal, inner cylindrical sleeve 17 and/or the inner surface of the metal, outer cylindrical sleeve, where each the at least one elastomeric seal retention groove 13 may be sized to accommodate one of the at least one elastomeric sealer 14 (or perhaps two grooves 13 would accommodate one sealer 14, as where one groove 13 is on the inner surface of the outer sleeve and the other groove 13 in oppositely established on the outer surface of the inner sleeve). Where two retention grooves 13 are used for the same sealer 14 (i.e., one as part of the outer surface of the inner sleeve and one oppositely established as part of the inner surface of the outer sleeve as shown in FIG. 13), such can be a type of inner cylindrical sleeve securer. Instead, or in addition (for additional retention strength), the inner cylindrical sleeve securer may comprise bolts and holes (the receptive holes for the bolts may be threaded), and possibly a flange. In one embodiment, the flange may include bolt holes that are above bolt holes of the mandrel 1 and that allow for passage therethrough of bolts for threaded engagement with the mandrel 1 bolt holes. In particular embodiments, the inner cylindrical sleeve securer may comprise a stop established below the metal, inner cylindrical sleeve. The securer may also include a washer 73 that may assist in maintaining an even spatial gap 69) and a snap ring 74 (that may assist in securing the inner sleeve against vertical translation relative to the mandrel).

In preferred embodiments, the apparatus allows for installation of the metal, inner cylindrical sleeve 17 in a final installation position within a power conductor hole 2 having a threaded inner surface without requiring twisting about the sleeve axis of the at least one electrical wire 46.

An inventive pressure tight sealing method, which may focus on the installation (as opposed to manufacture, for example) of the apparatus, may be described as comprising the steps of: threading a metal, outer cylindrical sleeve 65 having an outer surface 66 with threads into a threaded power conductor hole 2 of a mandrel 1; establishing a metal, inner cylindrical sleeve 17 within the metal, outer cylindrical sleeve; and establishing at least one elastomeric sealer 14 (e.g., an o-ring) between an outer surface of the metal, inner cylindrical sleeve 17 and an inner surface of the metal, outer cylindrical sleeve. Cured material may fill at least an axial portion of the metal, inner cylindrical sleeve 17 (e.g., a middle ½, or substantially all of the sleeve) and the metal, inner cylindrical sleeve 17 typically has two ends. Further, the threaded power conductor hole 2 defines a power conductor hole 2 axis (e.g., along the longitudinal axis of the spatial cylinder defined by the hole), and at least one electrical wire 46 passes through the cured material 44, from one of the ends to the other of the ends. At least a portion of each of the at least one electrical wire 46 is exposed electrical conductor 70 between the two ends and is in contact with (and bonded to) the cured material.

Additionally, the step of establishing at least one elastomeric sealer 14 between an outer surface of the metal, inner cylindrical sleeve 17 and an inner surface of the metal, outer cylindrical sleeve may comprise the step of either: forcing the metal, inner cylindrical sleeve 17 into the metal, inner cylindrical sleeve, along the power conductor hole 2 axis, and after performing the step of threading the metal, outer cylindrical sleeve having an outer surface with threads into the threaded power conductor hole 2 of the mandrel 1; or preventing rotation of the metal, inner cylindrical sleeve 17 about the power conductor hole 2 axis while performing the step of threading a metal, outer cylindrical sleeve having an outer surface with threads into a threaded power conductor hole 2 of a mandrel 1. Such prevention of rotation may be accomplished simply by holding the inner sleeve (whether by the wires, if sufficient, or via a tool attached to an end, such as a top end of the sleeve). Indeed, the method may allow for installation of the metal, inner cylindrical sleeve 17 in a final installation position within the threaded power conductor hole 2 without requiring twisting about the power conductor hole 2 axis of the at least one electrical wire. The method may further comprise the step of securing the metal, inner cylindrical sleeve 17 in fixed vertical position relative to the mandrel 1 through operation of an inner cylindrical sleeve securer 71, which may take the form of bolts and holes (some threaded), perhaps a flange, perhaps two retention rings (one on the outer surface of the inner sleeve and one on the inner surface of the outer sleeve), and/or perhaps a stop.

As with other embodiments, the cured material may be bonded to an inner surface of the metal, inner cylindrical sleeve 17 and to each the exposed electrical conductor. In certain embodiments, the cured material is flame resistant or fireproof, and the elastomeric sealer 14 is flame resistant or fireproof.

An inventive pressure tight sealing method, which may focus on the manufacture (as opposed to the installation, for example) of the apparatus, may be described as comprising the steps of: potting, with curable fluid 44, exposed electrical conductor (whether soldered, formerly stranded wire or not) of at least two electrical wires within a metal, inner cylindrical sleeve 17 to create a potted, metal, inner cylindrical sleeve; configuring (via machining, for example) a metal, outer sleeve to have: an outer surface with threads that threadedly engage threads of an inner surface of a power conductor hole 2 of a mandrel 1 (e.g., a well mandrel 1), and an inner surface that is radially larger than the outer surface of the metal, inner cylindrical sleeve. The method may further comprise the step of configuring at least one elastomeric sealer 14 for compressed establishment between the outer surface of the metal, inner cylindrical sleeve 17 and the inner surface of the metal, outer cylindrical sleeve.

The method may further comprise the step of bonding the curable fluid 44 to an inner surface of the metal, inner cylindrical sleeve 17 and to each the exposed electrical conductor. Such bonding may occur during curing of the curable fluid 44 to form a cured material. Potting, with curable fluid 44 (perhaps even flame resistant or fireproof curable fluid 44) may involve the step of potting with epoxy (which similarly may be flame resistant or fireproof epoxy). The method may further involve the step of establishing at least one elastomeric seal retention groove 13 in either the metal, outer cylindrical sleeve, or the metal, inner cylindrical sleeve; such may be done with well know manufacturing techniques (indeed all manufacturing type steps may involve well known manufacturing, fabrication, or machining techniques).

The manufacturing method may further comprise the step of stripping insulation from the electrical wires to generate the exposed electrical conductor. In the case where the stripped wires are stranded, the stripped wire may be soldered (or tinned) to generate exposed electrical conductor 70 in order to prevent flow in the interstitial spaces between the individual strands. Instead of tinning, it may be possible to strip stranded wire and move the two ends of the stripped portion together so that the strands all separate from each other, thereby allowing curable fluid 44 to flow between the strands. This, however, is a less preferred method, as it might unreliably separate the strands.

In the case where the at least two electrical wires are stranded, the method may further comprise the steps of stripping insulation from the electrical wires and soldering a length portion of the electrical wires to generate the exposed electrical conductor. The manufacturing method may further comprise the step of treating or geometrically varying the inner surface of the metal, inner cylindrical sleeve; and configuring an inner cylindrical sleeve securer operable to secure the inner cylindrical sleeve in fixed vertical position relative to the mandrel 1.

As can be easily understood from the foregoing, the basic concepts of the present invention may be embodied in a variety of ways. It involves both pressure sealing techniques as well as devices to accomplish the appropriate pressure seal. In this application, the pressure seal techniques are disclosed as part of the results shown to be achieved by the various devices described and as steps which are inherent to utilization. They are simply the natural result of utilizing the devices as intended and described. In addition, while some devices are disclosed, it should be understood that these not only accomplish certain methods but also can be varied in a number of ways. Importantly, as to all of the foregoing, all of these facets should be understood to be encompassed by this disclosure.

The discussion included in this application is intended to serve as a basic description. The reader should be aware that the specific discussion may not explicitly describe all embodiments possible; many alternatives are implicit. It also may not fully explain the generic nature of the invention and may not explicitly show how each feature or element can actually be representative of a broader function or of a great variety of alternative or equivalent elements. Again, these are implicitly included in this disclosure. Where the invention is described in device-oriented terminology, each element of the device implicitly performs a function. Apparatus claims may not only be included for the device described, but also method or process claims may be included to address the functions the invention and each element performs. Neither the description nor the terminology is intended to limit the scope of the claims that will be included in any subsequent patent application.

It should also be understood that a variety of changes may be made without departing from the essence of the invention. Such changes are also implicitly included in the description. They still fall within the scope of this invention. A broad disclosure encompassing both the explicit embodiment(s) shown, the great variety of implicit alternative embodiments, and the broad methods or processes and the like are encompassed by this disclosure and may be relied upon when drafting the claims for any subsequent patent application. It should be understood that such language changes and broader or more detailed claiming may be accomplished at a later date (such as by any required deadline) or in the event the applicant subsequently seeks a patent filing based on this filing. With this understanding, the reader should be aware that this disclosure is to be understood to support any subsequently filed patent application that may seek examination of as broad a base of claims as deemed within the applicant's right and may be designed to yield a patent covering numerous aspects of the invention both independently and as an overall system.

Further, each of the various elements of the invention and claims may also be achieved in a variety of manners. Additionally, when used or implied, an element is to be understood as encompassing individual as well as plural structures that may or may not be physically connected. This disclosure should be understood to encompass each such variation, be it a variation of an embodiment of any apparatus embodiment, a method or process embodiment, or even merely a variation of any element of these. Particularly, it should be understood that as the disclosure relates to elements of the invention, the words for each element may be expressed by equivalent apparatus terms or method terms—even if only the function or result is the same. Such equivalent, broader, or even more generic terms should be considered to be encompassed in the description of each element or action. Such terms can be substituted where desired to make explicit the implicitly broad coverage to which this invention is entitled. As but one example, it should be understood that all actions may be expressed as a means for taking that action or as an element which causes that action. Similarly, each physical element disclosed should be understood to encompass a disclosure of the action which that physical element facilitates. Regarding this last aspect, as but one example, the disclosure of a “seal” should be understood to encompass disclosure of the act of “sealing”—whether explicitly discussed or not—and, conversely, were there effectively disclosure of the act of “sealing”, such a disclosure should be understood to encompass disclosure of a “seal” and even a “means for sealing” Such changes and alternative terms are to be understood to be explicitly included in the description.

Any patents, publications, or other references mentioned in this application for patent are hereby incorporated by reference. Any priority case(s) claimed by this application is hereby appended and hereby incorporated by reference. In addition, as to each term used it should be understood that unless its utilization in this application is inconsistent with a broadly supporting interpretation, common dictionary definitions should be understood as incorporated for each term and all definitions, alternative terms, and synonyms such as contained in the Random House Webster's Unabridged Dictionary, second edition are hereby incorporated by reference. Finally, all references listed in the list of References To Be Incorporated By Reference In Accordance With The Provisional Patent Application or other information statement filed with the application are hereby appended and hereby incorporated by reference, however, as to each of the above, to the extent that such information or statements incorporated by reference might be considered inconsistent with the patenting of this/these invention(s) such statements are expressly not to be considered as made by the applicant(s).

Thus, the applicant(s) should be understood to have support to claim and make a statement of invention to at least: i) each of the pressure seal devices as herein disclosed and described, ii) the related methods disclosed and described, iii) similar, equivalent, and even implicit variations of each of these devices and methods, iv) those alternative designs which accomplish each of the functions shown as are disclosed and described, v) those alternative designs and methods which accomplish each of the functions shown as are implicit to accomplish that which is disclosed and described, vi) each feature, component, and step shown as separate and independent inventions, vii) the applications enhanced by the various systems or components disclosed, viii) the resulting products produced by such systems or components, ix) each system, method, and element shown or described as now applied to any specific field or devices mentioned, x) methods and apparatuses substantially as described hereinbefore and with reference to any of the accompanying examples, xi) the various combinations and permutations of each of the elements disclosed, xii) each potentially dependent claim or concept as a dependency on each and every one of the independent claims or concepts presented, and xiii) all inventions described herein.

With regard to claims whether now or later presented for examination, it should be understood that for practical reasons and so as to avoid great expansion of the examination burden, the applicant may at any time present only initial claims or perhaps only initial claims with only initial dependencies. The office and any third persons interested in potential scope of this or subsequent applications should understand that broader claims may be presented at a later date in this case, in a case claiming the benefit of this case, or in any continuation in spite of any preliminary amendments, other amendments, claim language, or arguments presented, thus throughout the pendency of any case there is no intention to disclaim or surrender any potential subject matter. It should be understood that if or when broader claims are presented, such may require that any relevant prior art that may have been considered at any prior time may need to be re-visited since it is possible that to the extent any amendments, claim language, or arguments presented in this or any subsequent application are considered as made to avoid such prior art, such reasons may be eliminated by later presented claims or the like. Both the examiner and any person otherwise interested in existing or later potential coverage, or considering if there has at any time been any possibility of an indication of disclaimer or surrender of potential coverage, should be aware that no such surrender or disclaimer is ever intended or ever exists in this or any subsequent application. Limitations such as arose in Hakim v. Cannon Avent Group, PLC, 479 F.3d 1313 (Fed. Cir 2007), or the like are expressly not intended in this or any subsequent related matter. In addition, support should be understood to exist to the degree required under new matter laws—including but not limited to European Patent Convention Article 123(2) and United States Patent Law 35 USC 132 or other such laws—to permit the addition of any of the various dependencies or other elements presented under one independent claim or concept as dependencies or elements under any other independent claim or concept. In drafting any claims at any time whether in this application or in any subsequent application, it should also be understood that the applicant has intended to capture as full and broad a scope of coverage as legally available. To the extent that insubstantial substitutes are made, to the extent that the applicant did not in fact draft any claim so as to literally encompass any particular embodiment, and to the extent otherwise applicable, the applicant should not be understood to have in any way intended to or actually relinquished such coverage as the applicant simply may not have been able to anticipate all eventualities; one skilled in the art, should not be reasonably expected to have drafted a claim that would have literally encompassed such alternative embodiments.

Further, if or when used, the use of the transitional phrase “comprising” is used to maintain the “open-end” claims herein, according to traditional claim interpretation. Thus, unless the context requires otherwise, it should be understood that the term “comprise” or variations such as “comprises” or “comprising”, are intended to imply the inclusion of a stated element or step or group of elements or steps but not the exclusion of any other element or step or group of elements or steps. Such terms should be interpreted in their most expansive form so as to afford the applicant the broadest coverage legally permissible.

Finally, any claims set forth at any time are hereby incorporated by reference as part of this description of the invention, and the applicant expressly reserves the right to use all of or a portion of such incorporated content of such claims as additional description to support any of or all of the claims or any element or component thereof, and the applicant further expressly reserves the right to move any portion of or all of the incorporated content of such claims or any element or component thereof from the description into the claims or vice-versa as necessary to define the matter for which protection is sought by this application or by any subsequent continuation, division, or continuation-in-part application thereof, or to obtain any benefit of, reduction in fees pursuant to, or to comply with the patent laws, rules, or regulations of any country or treaty, and such content incorporated by reference shall survive during the entire pendency of this application including any subsequent continuation, division, or continuation-in-part application thereof or any reissue or extension thereon.

1. A pressure tight seal apparatus comprising:
a metal, inner cylindrical sleeve defining a sleeve axis and having two ends, an inner surface and an outer surface;
cured material that fills at least an axial portion of said metal, inner cylindrical sleeve;
a metal, outer cylindrical sleeve having an outer surface with threads configured to engage threads of an inner surface of a power conductor hole of a mandrel, said metal, outer cylindrical sleeve established substantially around said metal, inner cylindrical sleeve and having an inner surface;
a spatial gap between said metal, inner cylindrical sleeve and said metal, outer cylindrical sleeve;
at least one elastomeric sealer established around said outer surface of said metal, inner cylindrical sleeve, between said outer surface and said inner surface of said metal, outer cylindrical sleeve, and in contact with both said surfaces;
at least one electrical wire passing through one of said two ends of said metal, inner cylindrical sleeve to the other of said two ends, each of said at least one electrical wire having at least a portion within said cured material that is exposed electrical conductor; and
an inner cylindrical sleeve securer that secures said metal, inner cylindrical sleeve in fixed vertical position relative to said mandrel, wherein said cured material is bonded to said inner surface of said metal, inner cylindrical sleeve and to each said exposed electrical conductor.

2. A pressure tight seal apparatus as described in claim 1 wherein said cured material comprises epoxy.

3. A pressure tight seal apparatus as described in claim 1 wherein said cured material is flame resistant or fireproof.

4. A pressure tight seal apparatus as described in claim 1 wherein said at least one elastomeric sealer is flame resistant or fireproof.

5. A pressure tight seal apparatus as described in claim 1 wherein said exposed electrical conductor of at least one of said at least one electrical wires is soldered, formerly stranded wire.

6. A pressure tight seal apparatus as described in claim 1 further comprising surface treatment or geometric variation of said inner surface of said metal, inner cylindrical sleeve.

7. A pressure tight seal apparatus as described in claim 1 further comprising at least one elastomeric seal retention groove established as part of said outer surface of said metal, inner cylindrical sleeve and/or said inner surface of said metal, outer cylindrical sleeve.

8. A pressure tight seal apparatus as described in claim 7 wherein each said at least one elastomeric seal retention groove sized to accommodate one of said at least one elastomeric sealer.

9. A pressure tight seal apparatus as described in claim 1 wherein said apparatus allows for installation of said metal, inner cylindrical sleeve in a final installation position within a power conductor hole having a threaded inner surface without requiring twisting about said sleeve axis of said at least one electrical wire.

10. A pressure tight seal apparatus as described in claim 1 wherein said inner cylindrical sleeve securer comprises a stop established below said metal, inner cylindrical sleeve.

11. A pressure tight seal apparatus as described in claim 1 wherein said inner cylindrical sleeve securer comprises bolts and holes, at least some of which are threaded.

12. A pressure tight seal apparatus as described in claim 1 wherein said inner cylindrical sleeve securer comprises a flange.

13. A pressure tight sealing method comprising the steps of:
threading a metal, outer cylindrical sleeve having an outer surface with threads into a threaded power conductor hole of a mandrel;
establishing a metal, inner cylindrical sleeve within said metal, outer cylindrical sleeve; and
establishing at least one elastomeric sealer between an outer surface of said metal, inner cylindrical sleeve and an inner surface of said metal, outer cylindrical sleeve;
wherein cured material fills at least an axial portion of said metal, inner cylindrical sleeve and said metal, inner cylindrical sleeve has two ends,
wherein said threaded power conductor hole defines a power conductor hole axis,
wherein at least one electrical wire passes through said cured material, from one of said ends to the other of said ends,
wherein at least a portion of each of said at least one electrical wire is exposed electrical conductor between said two ends and is in contact with said cured material,
wherein said step of establishing at least one elastomeric sealer between an outer surface of said metal, inner cylindrical sleeve and an inner surface of said metal, outer cylindrical sleeve comprises the step of either:
forcing said metal, inner cylindrical sleeve into said metal, inner cylindrical sleeve, along said power conductor hole axis, and after performing said step of threading said metal, outer cylindrical sleeve having an outer surface with threads into said threaded power conductor hole of said mandrel; or
preventing rotation of said metal, inner cylindrical sleeve about said power conductor hole axis while performing said step of threading a metal, outer cylindrical sleeve having an outer surface with threads into a threaded power conductor hole of a mandrel.

14. A pressure tight sealing method as described in claim 13 wherein said exposed electrical conductor of said at least one electrical wires is soldered, formerly stranded wire.

15. A pressure tight sealing method as described in claim 13 wherein said inner surface of said metal, inner cylindrical sleeve comprises surface treatment or geometric variation.

16. A pressure tight sealing method as described in claim 13 wherein said cured material is flame resistant or fireproof.

17. A pressure tight sealing method as described in claim 13 wherein said at least one elastomeric sealer is flame resistant or fireproof.

18. A pressure tight sealing method as described in claim 13 wherein said cured material is bonded to an inner surface of said metal, inner cylindrical sleeve and to each said exposed electrical conductor.

19. A pressure tight sealing method as described in claim 13 wherein said outer surface of said metal, inner cylindrical sleeve and/or said inner surface of said metal, outer cylindrical sleeve comprises at least one elastomeric seal retention groove.

20. A pressure tight sealing method as described in claim 19 wherein each said at least one elastomeric seal retention groove sized to accommodate one of said at least one elastomeric sealer.

21. A pressure tight sealing method as described in claim 13 wherein said method allows for installation of said metal, inner cylindrical sleeve in a final installation position within said threaded power conductor hole without requiring twisting about said power conductor hole axis of said at least one electrical wire.

22. A pressure tight sealing method as described in claim 13 further comprising the step of securing said metal, inner cylindrical sleeve in fixed vertical position relative to said mandrel through operation of an inner cylindrical sleeve securer.

23. A pressure tight sealing method as described in claim 22 wherein said inner cylindrical sleeve securer comprises bolts and holes, at least some of which are threaded.

24. A pressure tight sealing method as described in claim 22 wherein said inner cylindrical sleeve securer comprises a flange.

25-46. (canceled)
